(19) United States
(12) Patent Application Publication
(10) Pub. No.: US 2002/0084454 A1
(43) Pub. Date: Jul. 4, 2002

(54) Organic electro luminescence element having in plane electrode structure and method for fabricating the same

(76) Inventors: Sun Woong Kim, Seoul (KR); Woo Young Kim, Seoul (KR); Sung Hoo Ju, Kyoungki-do (KR); Joo Hyeon Lee, Kyoungki-do (KR)

Correspondence Address: LADAS & PARRY, 224 SOUTH MICHIGAN AVENUE, SUITE 1200, CHICAGO, IL, 60604, US

(21) Appl. No.: 10/034,530

(22) Filed: Dec. 28, 2001

(30) Foreign Application Priority Data
Dec. 29, 2000 (KR) 2000-86088

(51) Int. Cl. H01L 35/24

(52) U.S. Cl. 257/40

(57) ABSTRACT

Disclosed is an organic EL device having IPE structure and fabrication method thereof. The disclosed comprises a transparent substrate; a pixel anode fine line of anode electrode and a pixel cathode fine line of cathode electrode, formed on the transparent substrate, by turns; and an organic luminescence layer applied on the transparent substrate including the pixel anode fine line and the pixel cathode fine line.

### BACKGROUND OF THE INVENTION

1. Field of the Invention

The present invention relates to organic Electro Luminescence (hereinafter, referred to as EL) device having In Plane Electrode (hereinafter, referred to as IPE) structure, and more particularly, to organic EL device having IPE structure capable of easily forming electrodes and simplifying the processes by improving the anode and the cathode structures.

2. Description of the Related Art

Generally, organic EL panel is widely used as a next generation image display device, employed in car navigation system, display panel of game machine, monitor of desktop, notebook PC and wall type TV.

The conventional organic EL panel will be described in more detail with reference to accompanying FIGS. 1 and 2.

FIG. 1 is a drawing for showing a structure of organic EL device according to a conventional method.

FIG. 2 is a drawing for showing a luminescence mechanism of organic EL device.

Referring to FIG. 1, the conventional organic EL device 10 comprises an anode layer 3, a cathode layer 5 and an organic luminescence layer 7 formed between the layers.

Referring to FIG. 2, a positive hole + and an electron −, injected from electrodes, are recombined in the organic luminescence layer 7, thereby emitting light. In order to receive electric charges from the electrodes 3,5 of the organic EL device 10, an interface is formed between the organic luminescence layer 7 and the electrodes 3,5. The electric charges are injected through the interface to emit light.

As described above, the conventional organic EL device 10 includes an organic EL using a high molecule and that using a low molecule, wherein the high-molecule organic EL employs Spin Coating method or Ink Jet Printing method to form the organic luminescence layer 7 and the low-molecule organic EL vacuum deposition method.

According to the conventional high-molecule organic EL, the Indium Tin Oxide ITO anode layer 3 is formed in a shape of stripe and then, the organic luminescence layer 7 is applied as a single layer or 2-3 multilayer. And, the cathode layer 5 is formed in a shape of strip, thereby completing panel fabrication. The unexplained reference code 10 indicates a lower glass substrate.

The fabrication method of high-molecule organic EL, using Spin Coating will be described in the following.

FIG. 3 is a drawing for showing a fabrication process of organic EL, having a cathode formed by using a shadow mask.

Referring to FIG. 3, an ITO anode line 13 and an organic luminescence layer 17 are formed and then, a metal cathode 25 is vacuum deposited on a predetermined region by using a shadow mask 14.

According to the conventional high-molecule organic EL, the organic luminescence layer 17 is applied and then, the shadow mask 23 is formed with a desired resolution and adhered to the substrate whereon the organic luminescence layer 17 is applied. Afterwards, a metal source is vacuum deposited, thereby obtaining the cathode line 25 in a shape of stripe.

And, according to the low-molecule organic EL, it is possible to employ the shadow mask 14 in forming the cathode. However, it is general that counter-tapered cathode wall is formed and then, strip is directly formed by performing cathode vacuum deposition process without the shadow mask 23, in order to realize high resolution.

The shadow mask 23 is not employed because it is difficult to realize fine pattern of the shadow mask 23 and there are severe problems of metal line disconnection, mask dangling and substrate alignment.

In the high-molecule organic EL, the organic luminescence layer 17 is formed with organic solvent. Therefore, it is impossible to provide cathode wall (using PR), and the cathode is formed by using the metal shadow mask 23.

As a result, it is difficult to realize high resolution panel of high-molecule EL according to the conventional method.

The conventional high-molecule organic EL has improved properties such as low voltage driving, high efficiency luminescence and a single organic layer. Moreover, the organic layer is generally formed without vacuum deposition method, thereby reducing processing time and cost.

However, when the shadow mask is employed, the conventional organic EL has difficulty in obtaining high resolution because there are technical limitations in realizing fine patterns of the cathode. Therefore, it is required to induce stable cathode formation process using exposure process.

In the conventional passive matrix organic EL panel, medium and small-sized panels such as PDA and Car-Display are required to employ sub-electrode in order to lower resistance of the anode line.

Therefore, additional processes are required to form the sub-electrode, thereby increasing production cost. Recently, efforts are focused on development of material and panel structure without using the sub-electrode.

### SUMMARY OF THE INVENTION

Therefore, the present invention has been made to solve the above-mentioned problems and the object of the present invention is to provide an organic EL device having IPE structure, capable of easy formation of electrodes and light emission without additional devices, by alternatively forming the cathode and the anode on a glass substrate.

And, another object of the present invention is to provide an organic EL device capable of solving a problem of cathode shadow mask due to the conventional up and down electrode structure and the method of applying high molecule solved in organic solvent and problems of shadow mask fabrication and panel application, having a pixel structure suitable for high resolution organic EL panel.

In order to accomplish the above-mentioned objects, the present invention comprises: a transparent substrate; a pixel anode fine line of anode electrode and a pixel cathode fine line of cathode electrode alternatively formed on the transparent substrate; and an organic luminescence layer applied on the transparent substrate including the pixel anode fine line and the pixel cathode fine line.

And, the present invention comprises the steps of: providing a transparent substrate; forming a pixel anode fine line of anode electrode and a pixel cathode fine lien of cathode electrode on the transparent substrate, by turns; and forming an organic luminescence layer on the transparent substrate including the pixel anode fine and the pixel cathode fine line.

And, according to the present invention, the anode electrode is capable of realizing luminescent pixel by using anode electrode as a metal material, not by using ITO as a transparent electrode, and an insulating layer is formed between the anode electrode and the cathode electrode in order to prevent disconnection.

Moreover, the organic EL device is capable of employing high molecule and single-layered luminescent material by forming the cathode line without shadow mask and luminescence of the organic luminescence layer is formed between the pixel anode fine line and the pixel cathode fine line and it is possible to employ nonconductive materials in the panel substrate. The anode electrode and the cathode electrode have a thickness of hundreds of to thousands of Å.

The insulating layer has a thickness of hundreds of Å to several μm and the pixel anode and cathode fine lines have a structure that the cross section of electrode is formed vertical through a dry etch process and therefore, the distance is uniform in up and down and the width is narrowed, thereby preventing increase of driving voltage.

The organic luminescence layer employs one high molecule material selected from a group comprising solvent, PPV, MEH-PPV, Polythiophene, Polypyrrole and OC₁C₁₀.

And, the distance between pixel fine lines is thousands of Å.

### BRIEF DESCRIPTION OF THE DRAWINGS

FIG. 1 is a drawing for showing a structure of organic EL device according to the conventional method.

FIG. 2 is a drawing for showing luminescence mechanism of general organic EL device.

FIG. 3 is a drawing for showing a method of fabricating organic EL, having the cathode formed by using shadow mask, according to the conventional method.

FIG. 4 is a drawing for showing the operation principle of unit pixel having a IPE structure according to an embodiment of the present invention.

FIGS. 5 to 8 are drawings for showing formation processes of organic EL panel having an electrode pattern of IPE structure according to the present invention.

FIG. 10 is a drawing for showing a pixel electrode pattern and a full color organic EL panel according to another embodiment of the present invention.

FIG. 11 is a drawing for showing electrode arrangement in organic EL panel having IPE structure according to the present invention.

The above objects, and other features and advantages of the present invention will become more apparent after reading the following detailed description when taken in conjunction with the drawings.

### DETAILED DESCRIPTION OF THE PRESENT INVENTION

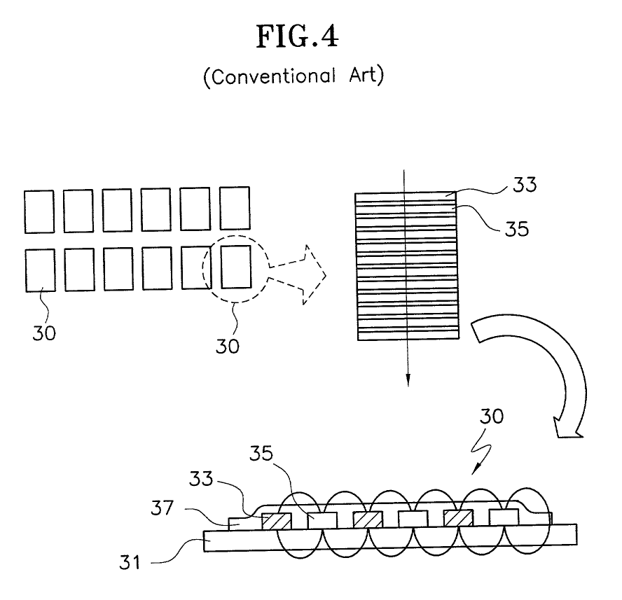

FIG. 4 is a drawing for showing the operation principle of unit pixel having IPE structure according to a preferred embodiment of the present invention.

According to the present invention, the organic EL device has a In Plane Electrode IPE structure, wherein the anode 33 and the cathode 35 are horizontally crossed on a glass substrate 31, as shown in FIG. 4 enlarging a unit pixel 24 having IPE structure.

And, according to the present invention, contrary to the conventional electrode having up and down structure, the electrodes 33,35 are formed on the same plane, thereby emitting light between the electrodes.

After the electrodes 33,35 are formed, an organic luminescence layer 37 is finally formed.

Therefore, the electrodes 33,35 are formed by using overall exposure process employed in recent semiconductor process. As a result, there are no problems due to metal shadow mask, such as limitations in fine pattern of shadow mask, fine line disconnection, line dangling and alignment with substrate.

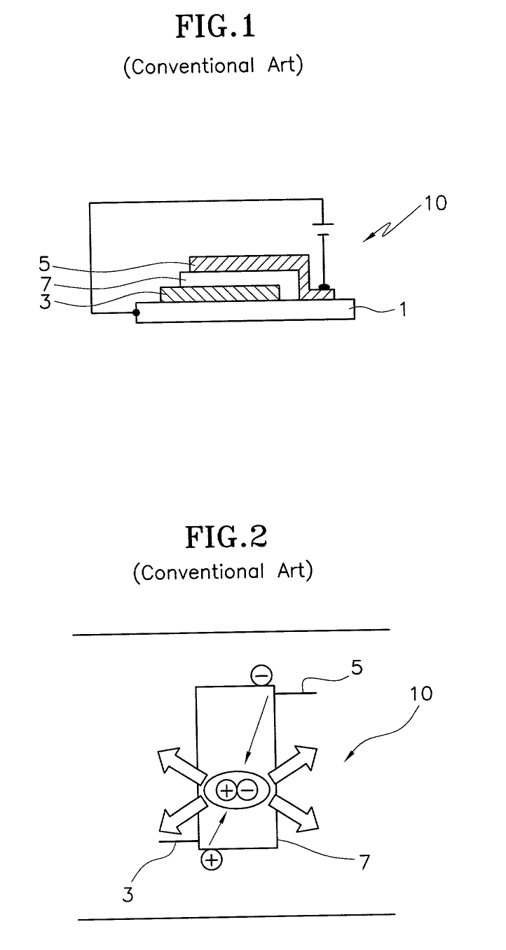

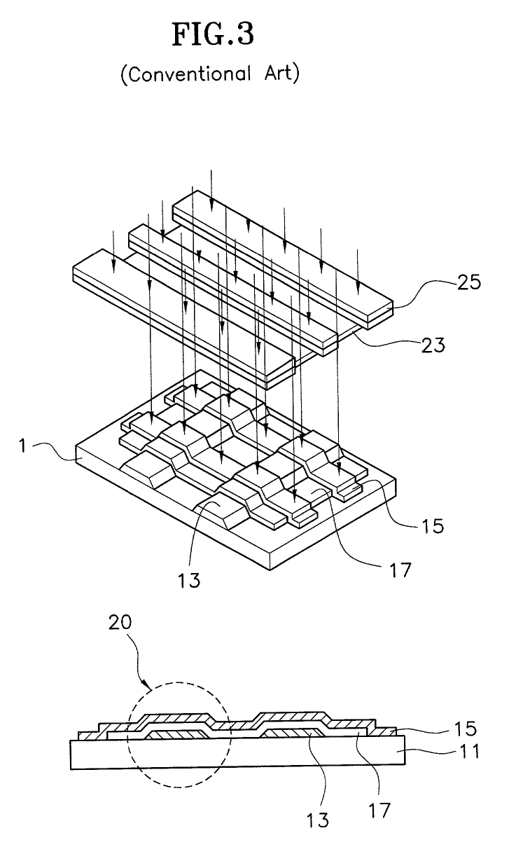

According to the present invention, luminescence is accomplished not on the organic luminescence layer 7 formed between the electrodes 3,5 as shown in FIG. 1, but on an organic luminescence layer 37 applied on the horizontal space of each electrode 33,35.

And, according to the present invention, it is not required to employ the transparent anode electrode 33. Therefore, it is possible to skip the formation process of sub-electrode, generated in employing ITO, thereby simplifying the fabrication process and reducing manufacturing cost.

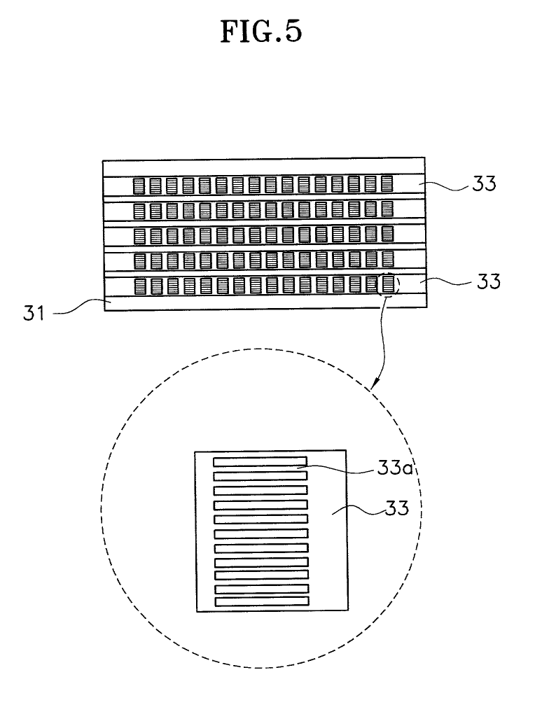

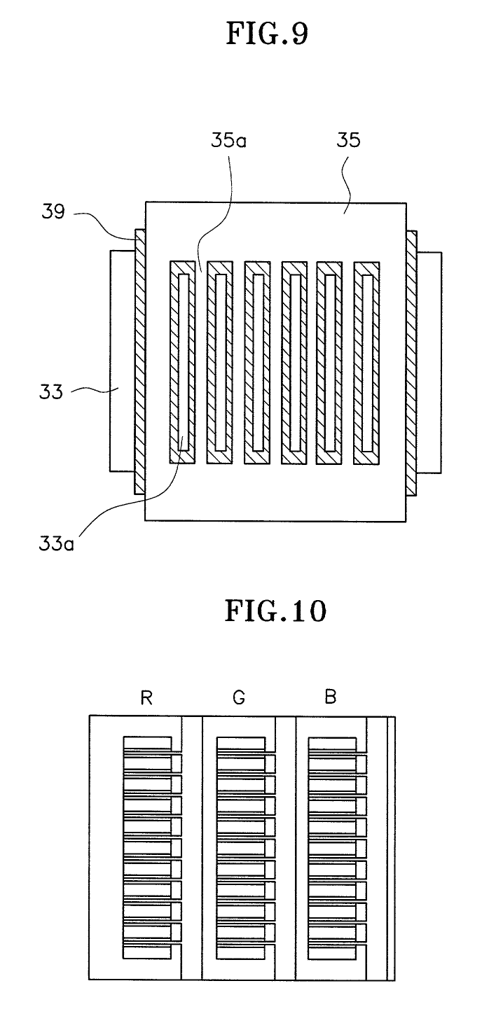

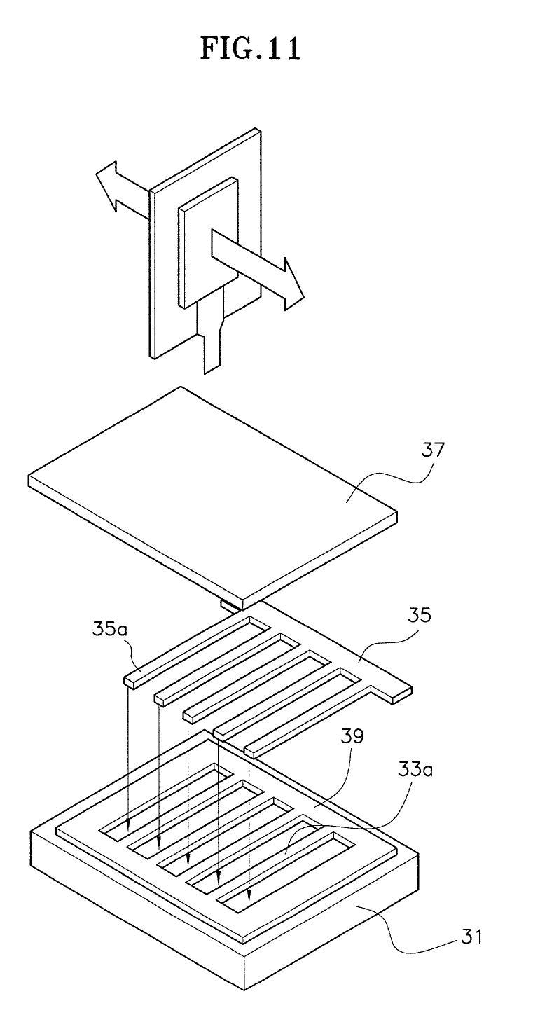

FIGS. 5 to 8 are drawings for showing formation processes of organic EL panel having electrode pattern of IPE structure according to the present invention and FIG. 9 is a drawing for showing a pixel electrode pattern and full color organic EL panel according to another embodiment of the present invention, and FIG. 10 is a drawing for showing electrode arrangement in organic EL panel having IPE structure according to the present invention.

Referring to FIG. 5, the anode 33 and the cathode 35 are formed on the same plane. That is, it is not required that the ITO transparent electrode is firstly formed, and the anode and the cathode are formed regardless of the sequence.

And, light emitted from the pixel is observed on the opposite of cathode electrode through the transparent substrate. That is, according to the IPE structure of the present invention, luminescence is accomplished between electrodes on the same plane, unlike conventional organic EL panel employing transparent glass substrate and ITO transparent electrode. Therefore, it is not required to employ transparent substrate except for observation from both sides.

And, when the anode electrode 33 is formed, it is possible to employ various other metals having high work function, instead of ITO having high resistance.

Referring to FIG. 5, the anode electrode 33, having a shape of stripe, comprises pixel anode fine line 33a having IPE structure on the part corresponding to each pixel. The anode electrode 33 has a thickness of hundreds of Å to thousands of Å, depending on the material properties and processes.

The pixel anode fine line 33a has electrode interface and profile in relation to luminescence, corresponding to pixel cathode fine line 35a to be formed in following processes.

The pixel anode fine line 33a can be patterned by wet etch method using exposure process. However, it is desirable that the electrode profile be vertical by dry etch method as an anisotropy etch method, in order to maintain uniform profile separation with the pixel cathode fine line 35a and that the width be narrowed to prevent increase of driving voltage.

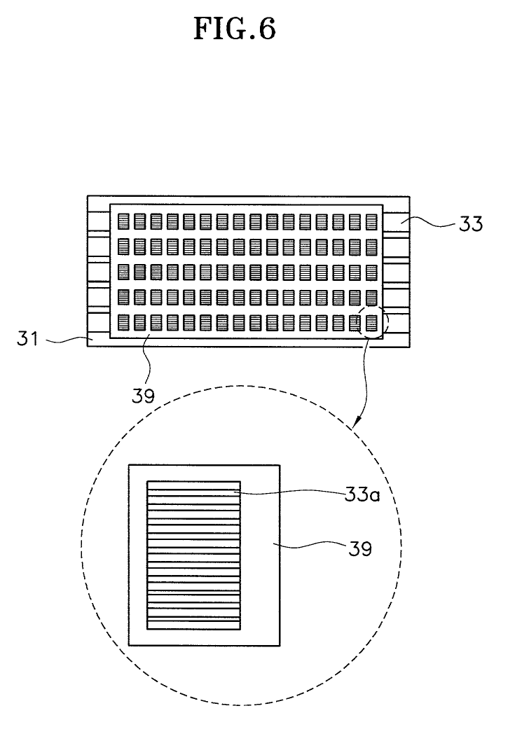

Referring to FIG. 6, after the anode electrode 33 is formed, an insulating layer 39 is patterned to define pixel opening.

The insulating layer 39 is employed to prevent disconnection of cathode line 35 to be formed and the anode line 33 and to define opening of pixel. The insulating layer 39 has a thickness of hundreds of Å to several μm, depending on the device properties and the processes.

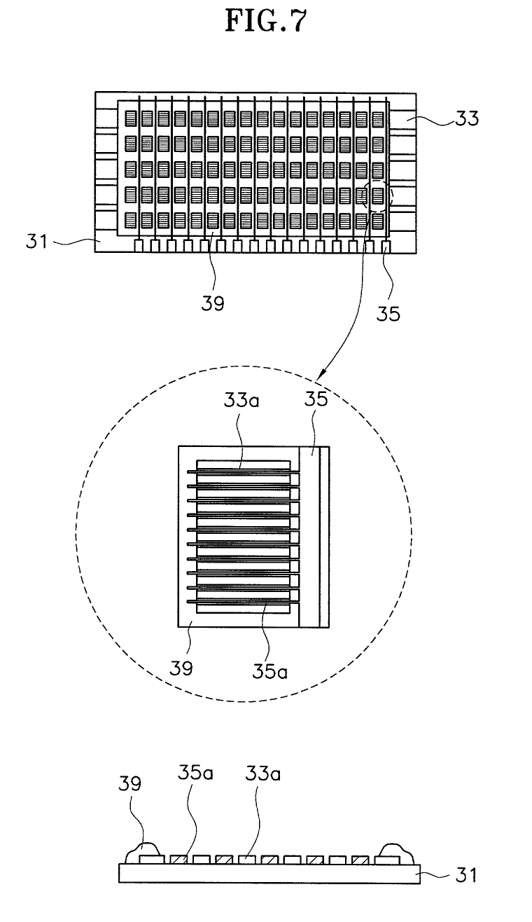

FIG. 7 is a drawing for showing cathode pattern of organic EL panel having IPE structure according to the present invention, wherein the cathode line 35 is formed to be perpendicular to the anode line 33 from pad and pixel electrode fine line 35a of each pixel is arranged to be parallel with pixel anode fine line 33a of corresponding pixel, on the transparent substrate 31. The pixel electrode fine line 35a of each pixel and the pixel anode fine line 33a of corresponding pixel is formed by turns on the transparent substrate 31.

Similar to the anode layer 33, the cathode layer 35 has a thickness of hundreds of Å to thousands of Å, by using semiconductor exposure process without vacuum deposition. Therefore, it is advantageously applied to alignment of fine pattern and pixel cathode fine line, thereby solving problems of conventional metal mask.

And, similar to the pixel anode fine line 33a, the pixel cathode fine line 35a has a vertical profile by dry etch as an anisotropy etch process in order to maintain uniform profile separation with the pixel anode fine line 35a and the width is narrowed to prevent increase of driving voltage.

According to the IPE electrode, the anode 33 and the cathode 35 are made of conventional ITO or other metals having work function of cathode metal, thereby improving properties of organic EL device.

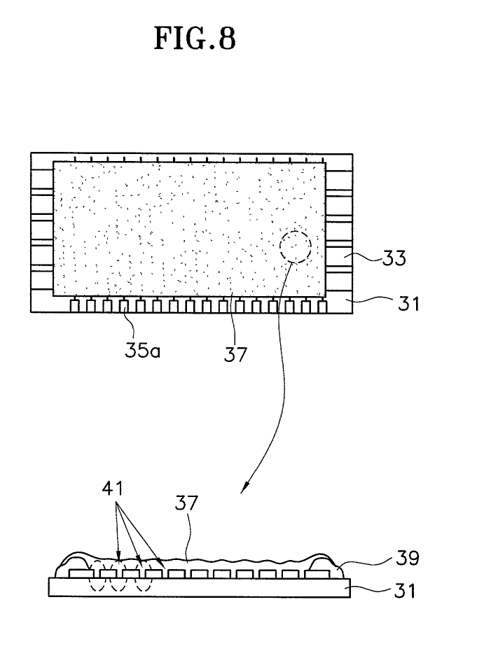

FIG. 8 shows a plane view of organic EL panel and cross section of unit pixel after the cathode electrode is formed and then, high molecule luminescence layer is applied on the IPE organic EL array. Referring to FIG. 8, the applied high molecule materials include solvent, obtained by mixing the positive hole and the electron transport layer with luminescence additives, and other single layer luminescence materials such as PPV, MEH-PPV, Polythiophone, Polypyrrole and OC₁C₁₀.

The organic layer is applied in accordance with conventional methods such as spin coating and inkjet printing. Generally, the organic luminescence layer 37 between the anode 33 and the cathode 35 has a thickness of approximately 2000 Å.

According to the present invention, the pixel fine lines 33a, 35a maintain separation of thousands of Å. Therefore, it is possible to control minimum separation of the pixel cathode fine line 35a and the pixel anode fine line 33a, employ anode metal materials having high conductivity and work function instead of ITO and develop high molecule organic materials having high efficiency.

As a result, it is possible to fabricate panel having high resolution and it is also possible to simplify the fabrication processes since the panel is completed without using shadow mask.

And, referring to FIG. 8, the luminescence unit 41 is arranged between the pixel anode fine line 33a and the pixel cathode fine line 35a, not between upper and lower electrodes as shown in the conventional structure, and the cathode pattern 35 is formed prior to applying the organic layer 37 without any limitation of the formation.

And, it is possible that the pixel electrode fine lines 33a, 35a are formed by changing the direction of electrode, as shown in FIG. 9. When it is a pixel of full color panel, each sub pixel is formed, as shown in FIG. 10.

In this case, the electrode is formed by controlling the minor axis direction length of pixel electrode fine lines 33a, 35a in the single color luminescence panel. That is, it is possible to be applied without severe change of fabrication processes.

In the conventional method, sub-electrode is employed to solve ITO anode resistance problem of medium and small-sized panel due to necessity of transparent electrode. However, according to IPE structure of the present invention, it is possible to employ metal electrode having low resistance without transparent electrode, thereby skipping sub-electrode formation process. Therefore, it has advantages of simplifying processes and reducing manufacturing cost.

Desirably, it is also possible to fabricate the panel in accordance with vacuum deposition method if using low molecule organic materials having high efficiency with low voltage and capable of single layer luminescence, as well as high molecule organic EL.

According to the present invention, electrode array process is completed prior to organic luminescence layer formation process, unlike the conventional method wherein array process depends on organic materials and organic layer process. Therefore, it can be advantageously applied to organic EL panel.

As described above, according to the present invention, a pixel anode fine line and a pixel cathode fine line are formed on the same plane, by turns and the pixel emits light between the lines.

Therefore, it is not necessarily required that the emitted light pass through ITO and transparent substrate. As a result, it is possible to employ various materials and to realize work function in an improved condition.

And, it is possible to employ other metals having improved electrical properties as anode electrode, instead of ITO, thereby skipping sub-electrode formation process. Moreover, the cathode electrode is formed prior to applying organic luminescence layer, without shadow mask, thereby realizing pixel of high resolution.

Although the preferred embodiment of this invention has been disclosed for illustrative purpose, those skilled in the art will appreciate that various modifications, additions and substitutions are possible, without departing from the scope and spirit of the invention.

What is claimed is:

1. An organic EL device having IPE structure comprising:
a transparent substrate;
a pixel anode fine line of anode electrode and a pixel cathode fine line of cathode electrode, alternatively formed on the transparent substrate; and
an organic luminescence layer applied on the transparent substrate including the pixel anode fine line and the pixel cathode fine line.

2. The organic EL device having IPE structure according to claim 1, wherein the anode electrode employs metal materials as luminescence pixel.

3. The organic EL device having IPE structure according to claim 1, wherein an insulating layer is formed between the anode electrode and the cathode electrode in order to prevent disconnection.

4. The organic EL device having IPE structure according to claim 1, wherein the organic EL device employs high molecule and single layer luminescence materials.

5. The organic EL device having IPE structure according to claim 1, wherein luminescence of organic luminescence layer is accomplished between the pixel anode and the pixel cathode electrode fine lines.

6. The organic EL device having IPE structure according to claim 1, wherein the transparent substrate is made of nonconductive materials.

7. The organic EL device having IPE structure according to claim 1, wherein the anode and the cathode electrodes have a thickness of hundreds of Å to thousands of Å.

8. The organic EL device having IPE structure according to claim 3, wherein the insulating layer has a thickness of hundreds of Å to several μm.

9. The organic EL device having IPE structure according to claim 1, wherein the organic luminescence layer is made of one high molecule material selected from a group comprising solvent, PPV, MEH-PPV, Polythiophene, Polypyrrole and OC₁C₁₀.

10. The organic EL device having IPE structure according to claim 1, wherein the pixel fine lines maintain the separation of thousands Å.

11. A method of fabricating organic EL device having IPE structure comprising the steps of:
providing a transparent substrate;
alternatively forming a pixel anode fine line of anode electrode and a pixel cathode fine line of cathode electrode on the transparent substrate; and
forming an organic luminescence layer on the transparent substrate including the pixel anode fine line and the pixel cathode fine line.

12. The method of fabricating organic EL device having IPE structure according to claim 11, wherein the anode electrode employs metal materials as luminescence pixel.

13. The method of fabricating organic EL device having IPE structure according to claim 11, wherein further comprising the step of forming an insulating layer in order to prevent disconnection between the anode electrode and the cathode electrode.

14. The method of fabricating organic EL device having IPE structure according to claim 11, wherein the organic EL device employs high molecule and single layer luminescence materials.

15. The method of fabricating organic EL device having IPE structure according to claim 11, wherein luminescence of organic luminescence layer is accomplished between the pixel anode and the pixel cathode fine lines.

16. The method of fabricating organic EL device having IPE structure according to claim 11, wherein the transparent substrate is made of nonconductive materials.

17. The method of fabricating organic EL device having IPE structure according to claim 11, wherein the anode and the cathode electrodes have a thickness of hundreds of Å to thousands of Å.

18. The method of fabricating organic EL device having IPE structure according to claim 13, wherein the insulating layer has a thickness of hundreds of Å to several μm.

19. The method of fabricating organic EL device having IPE structure according to claim 11, wherein the pixel anode and the pixel cathode fine lines have vertical profile through dry etch and profile separation is uniformly maintained up and down.

20. The method of fabricating organic EL device having IPE structure according to claim 11, wherein the organic luminescence layer is made of one high molecule material selected from a group comprising solvent, PPV, MEH-PPV, Polythiophene, Polypyrrole and OC₁C₁₀.

21. The method of fabricating organic EL device having IPE structure according to claim 11, wherein the pixel fine lines maintain the separation of thousands Å.
